(19) United States
(12) Patent Application Publication
(10) Pub. No.: US 2013/0208207 A1
(43) Pub. Date: Aug. 15, 2013

(54) DISPLAY DEVICE SUBSTRATE, METHOD FOR PRODUCING THE SAME, AND DISPLAY DEVICE

(71) Applicants: Tetsuya Okamoto, Osaka-shi (JP); Yoshiki Nakatani, Osaka-shi (JP); Yudai Takanishi, Osaka-shi (JP); Yohsuke Kanzaki, Osaka-shi (JP); Yuhichi Saitoh, Osaka-shi (JP)

(72) Inventors: Tetsuya Okamoto, Osaka-shi (JP); Yoshiki Nakatani, Osaka-shi (JP); Yudai Takanishi, Osaka-shi (JP); Yohsuke Kanzaki, Osaka-shi (JP); Yuhichi Saitoh, Osaka-shi (JP)

(73) Assignee: Sharp Kabushiki Kaisha, Osaka-shi ,Osaka (JP)

(21) Appl. No.: 13/806,235

(22) PCT Filed: May 24, 2011
(86) PCT No.: PCT/JP2011/002875

§ 371 Date: Feb. 6, 2013

(30) Foreign Application Priority Data
Jun. 25, 2010 (JP) 2010-145263
Sep. 3, 2010 (JP) 2010-198117

(51) Int. Cl. H01L 29/04; G02F 1/1368

(52) U.S. Cl. CPC H01L 29/04; G02F 1/1368
USPC 349/46; 257/59; 438/34

(57) ABSTRACT

An active matrix substrate (20) includes: a gate electrode (11) provided on an insulating substrate (10a); a gate insulating layer (12) covering the gate electrode (11); an oxide semiconductor layer (13) provided on the gate insulating layer (12); and a protective layer (17) covering the oxide semiconductor layer (13). The active matrix substrate (20) has a display region (D) where an image is displayed and a gate terminal region (Ts) located around the display region (D) and including a gate terminal (26) for connection to an external circuit. The gate terminal (26) includes a terminal line (21) provided on the insulating substrate (10a). The terminal line (26) is made of a conductive material different from a material constituting the oxide semiconductor layer (13).

### TECHNICAL FIELD

The present disclosure generally relates to substrates for display devices (hereinafter referred to as “display device substrates”), and more particularly to a display device substrate including a thin-film transistor using an oxide semiconductor layer, a method for fabricating the substrate, and a display device.

### BACKGROUND ART

Liquid crystal display devices having the advantages of small thickness, lightweight, drivability at low voltages, and low power consumption have been recently used as display panels of various types of mobile terminal devices, e.g., cell phones and portable game devices, and electronic equipment, e.g., as laptop computers.

In general, a liquid crystal display device includes a pair of opposing substrates (i.e., an active matrix substrate and a counter substrate), a liquid crystal layer provided between the substrates, and a sealing material bonding the substrates together and having a frame shape to enclose liquid crystal between the substrates.

The liquid crystal display device has a display region including a plurality of pixels and used for displaying an image on a portion surrounded by the sealing material, and also has a terminal region (a drive circuit region) defined in a portion of the active matrix substrate projecting from the counter substrate when viewed from above.

In the active matrix substrate, a thin-film transistor (hereinafter referred to as a “TFT”), for example, is provided as a switching device in each of the pixels, which are minimum units of an image.

The active matrix substrate includes an insulating substrate and also includes, in the display region, a plurality of scanning lines extending in parallel with each other on the insulating substrate and a plurality of parallel signal lines orthogonal to the scanning lines. The above-mentioned TFT is provided at each of intersections of the scanning lines and the signal lines, i.e., for each pixel. The signal lines extend to the terminal region, and are connected to source terminals in the terminal region.

A general bottom-gate TFT includes, for example, a gate electrode provided on an insulating substrate, a gate insulating layer covering the gate electrode, an island-shape semiconductor layer located on the gate insulating layer and overlapping the gate electrode, and a source electrode and a drain electrode opposing to each other on the semiconductor layer.

For a recent active matrix substrate, instead of a conventional TFT using a semiconductor layer of amorphous silicon, a TFT using a semiconductor layer of oxide semiconductor (hereinafter also referred to as an “oxide semiconductor layer”) has been proposed as a switching device of each pixel which is a minimum unit of an image. This active matrix substrate can be formed by forming a pattern of a photosensitive film having portions with different thicknesses through two light exposure processes with a photoetching system including two light exposing units, and using this pattern as four photomasks, etching a multi-layered thin film at a time. The oxide semiconductor layer formed on the gate insulating layer and the signal lines (source bus lines) provided on this oxide semiconductor layer constitute the above-described source terminals (see, for example, Patent Document 1).

### CITATION LIST

### Patent Document

PATENT DOCUMENT 1: Japanese Patent Publication No. 2001-319876

### SUMMARY OF THE INVENTION

### Technical Problem

In the active matrix substrate described in Patent Document 1, however, since the source terminals are made of an oxide semiconductor layer, oxide semiconductor constituting the oxide semiconductor layer might be exposed at the side surfaces of the source terminals. When exposed, oxide semiconductor, whose corrosion resistance is lower than that of amorphous silicon, comes into contact with the air to be corroded by moisture in the air, and thereby, peeled off, resulting in an electrical continuity failure of the source terminals.

It is therefore an object of the present disclosure to provide a thin-film transistor substrate capable of preventing an electrical continuity failure of source terminals due to corrosion of oxide semiconductor, a method for fabricating such a substrate, and a display device.

### Solution to the Problem

To achieve the object, a display device substrate according to the present disclosure includes: an insulating substrate; a gate electrode provided on the insulating substrate; a gate insulating layer covering the gate electrode; an oxide semiconductor layer provided on the gate insulating layer and having a channel region overlapping with the gate electrode; source and drain electrodes provided on the oxide semiconductor layer, overlapping with the gate electrode, and facing each other with the channel region sandwiched therebetween; a protective layer covering the oxide semiconductor layer and the source and drain electrodes; and a pixel electrode provided on the protective layer, wherein the display device substrate has a display region where an image is displayed and a terminal region located around the display region and including a terminal for connection to an external circuit, the terminal includes a terminal line provided on the insulating substrate, and the terminal line is made of a conductive material different from a material constituting the oxide semiconductor layer.

In this configuration, the terminal line constituting the terminal is made of the conductive material different from a material constituting the oxide semiconductor layer. Thus, it is possible to prevent exposure of the material constituting the oxide semiconductor layer at the side surface of the terminal. Accordingly, it is possible to prevent contact of the material constituting the oxide semiconductor layer with the air, and thereby, to prevent corrosion by moisture contained in the air. As a result, an electrical continuity failure of the terminal due to corrosion of the material constituting the oxide semiconductor layer can be prevented.

In addition, since the terminal line constituting the terminal is made of the conductive material different from the material constituting the oxide semiconductor layer, oxide semiconductor having a high etching rate does not need to be etched in forming the terminal. This can prevent over-etching of the terminal line constituting the terminal, resulting in prevention of an electrical continuity failure of the terminal due to increased resistance and disconnection of the terminal line.

Another display device substrate according to the present disclosure includes: an insulating substrate; a gate electrode provided on the insulating substrate; a gate insulating layer covering the gate electrode; an oxide semiconductor layer provided on the gate insulating layer and having a channel region overlapping with the gate electrode; source and drain electrodes provided on the oxide semiconductor layer, overlapping with the gate electrode, and facing each other with the channel region sandwiched therebetween; a protective layer covering the oxide semiconductor layer and the source and drain electrodes; an insulating layer provided on the protective layer; and a pixel electrode provided on the insulating layer, wherein the display device substrate has a display region where an image is displayed and a terminal region located around the display region and including a terminal for connection to an external circuit, the terminal includes a terminal line provided on the insulating substrate, and the terminal line is made of a conductive material different from a material constituting the oxide semiconductor layer.

In this configuration, the terminal line constituting the terminal is made of the conductive material different from a material constituting the oxide semiconductor layer. Thus, it is possible to prevent exposure of the material constituting the oxide semiconductor layer at the side surface of the terminal. Accordingly, it is possible to prevent contact of the material constituting the oxide semiconductor layer with the air, and thereby, to prevent corrosion by moisture contained in the air. As a result, an electrical continuity failure of the terminal due to corrosion of the material constituting the oxide semiconductor layer can be prevented.

In addition, since the terminal line constituting the terminal is made of the conductive material different from the material constituting the oxide semiconductor layer, oxide semiconductor having a high etching rate does not need to be etched in forming the terminal. This can eliminate the necessity of over-etching of the terminal line constituting the terminal, resulting in prevention of an electrical continuity failure of the terminal due to increased resistance and disconnection of the terminal line.

In the display device substrate of the present disclosure, the terminal line and the gate electrode may be made of an identical material.

In this configuration, the terminal line and the gate electrode can be formed at the same time. Thus, the terminal line can be easily formed, and an increase in the number of process steps can be reduced, resulting in reduction of the manufacturing cost.

In the display device substrate of the present disclosure, the terminal line may include a first terminal line provided on the insulating substrate and a second terminal line provided on the first terminal line.

In the display device substrate of the present disclosure, the first terminal line and the gate electrode may be made of an identical material, and the second terminal line and the pixel electrode may be made of an identical material.

In this configuration, the first terminal line and the gate electrode can be formed at the same time, and the second terminal line and the pixel electrode can be formed at the same time. Thus, the first terminal line and the second terminal line can be easily formed, and an increase in the number of process steps can be reduced, resulting in reduction of the manufacturing cost.

In the display device substrate of the present disclosure, the oxide semiconductor layer may be made of indium gallium zinc oxide (IGZO).

A display device according to the present disclosure includes the display device substrate of the present disclosure; another display device substrate opposed to the display device substrate; and a display medium layer provided between the display device substrate and the another display device substrate.

The display device of the present disclosure may further include a sealing material held between the display device substrate and the another display device substrate and having a frame shape to enclose the display medium layer between the display device substrate and the another display device substrate, and the sealing material may be provided on a surface of the terminal line.

In this configuration, since the sealing material is provided on the surface of the terminal line made of the conductive material different from the material constituting the oxide semiconductor layer, it is possible to prevent a variation of stress on the sealing material due to expansion and contraction of bubbles included in the material constituting the oxide semiconductor layer. As a result, occurrence of peeling and cracks in the sealing material caused by the material constituting the oxide semiconductor layer can be prevented.

In the display device of the present disclosure, the display medium layer may be a liquid crystal layer.

A method for forming a display device substrate according to the present disclosure is a method for forming a display device substrate including: an insulating substrate; a gate electrode provided on the insulating substrate; a gate insulating layer covering the gate electrode; an oxide semiconductor layer provided on the gate insulating layer and having a channel region overlapping with the gate electrode; source and drain electrodes provided on the oxide semiconductor layer, overlapping with the gate electrode, and facing each other with the channel region sandwiched therebetween; a protective layer covering the oxide semiconductor layer and the source and drain electrodes; and a pixel electrode provided on the protective layer, wherein the display device substrate has a display region where an image is displayed and a terminal region located around the display region and including a terminal for connection to an external circuit, and the method includes: a first terminal line formation step of depositing a first conductive film on the insulating substrate and patterning the first conductive film with a first photomask, thereby forming the gate electrode and a first terminal line; a gate insulating layer formation step of forming the gate insulating layer such that the gate insulating layer covers the gate electrode; an oxide semiconductor layer formation step of depositing an oxide semiconductor film on the gate insulating layer, depositing a metal film on the oxide semiconductor film, and patterning the oxide semiconductor film and the metal film with a second photomask, thereby forming the oxide semiconductor layer and the source and drain electrodes; a protective layer formation step of forming the protective layer such that the protective layer covers the oxide semiconductor layer and the source and drain electrodes; a contact hole formation step of patterning the protective layer with a third photomask, thereby forming a contact hole in the protective layer such that the contact hole reaches the drain electrode; and a terminal formation step of depositing a second conductive film on the protective layer and patterning the second conductive film with a fourth photomask, thereby forming the pixel electrode and a second terminal line on the first terminal line such that the terminal including the first terminal line and the second terminal line is formed.

In this configuration, the first terminal line and the second terminal line constituting the terminal are made of a conductive material different from a material constituting the oxide semiconductor layer. Thus, it is possible to prevent exposure of the material constituting the oxide semiconductor layer at the side surface of the terminal. Accordingly, it is possible to prevent contact of the material constituting the oxide semiconductor layer with the air, and thereby, to prevent corrosion by moisture contained in the air. As a result, an electrical continuity failure of the terminal due to corrosion of the material constituting the oxide semiconductor layer can be prevented.

In addition, since the first terminal line and the second terminal line constituting the terminal are made of the conductive material different from the material constituting the oxide semiconductor layer, oxide semiconductor having a high etching rate does not need to be etched in forming the terminal. This can prevent over-etching of the first terminal line and the second terminal line constituting the terminal, resulting in prevention of an electrical continuity failure of the terminal due to increased resistance and disconnection of the first terminal line and the second terminal line.

In formation of the display device substrate, the first photomask is used in the first terminal line formation step, the second photomask is used in the oxide semiconductor layer formation step, the third photomask is used in the contact hole formation step, and the fourth photomask is used in the terminal formation step. That is, four photomasks are used in total. Thus, as compared to a conventional process using four masks, occurrence of an electrical continuity failure of the terminal due to corrosion of the material constituting the oxide semiconductor layer can be prevented without an increase in the number of photomasks.

Another method for forming a display device substrate according to the present disclosure is a method for forming a display device substrate including: an insulating substrate; a gate electrode provided on the insulating substrate; a gate insulating layer covering the gate electrode; an oxide semiconductor layer provided on the gate insulating layer and having a channel region overlapping with the gate electrode; source and drain electrodes provided on the oxide semiconductor layer, overlapping with the gate electrode, and facing each other with the channel region sandwiched therebetween; a protective layer covering the oxide semiconductor layer and the source and drain electrodes; an insulating layer provided on the protective layer; and a pixel electrode provided on the insulating layer, wherein the display device substrate has a display region where an image is displayed and a terminal region located around the display region and including a terminal for connection to an external circuit, and the method includes: a first terminal line formation step of depositing a first conductive film on the insulating substrate and patterning the first conductive film with a first photomask, thereby forming the gate electrode and a first terminal line; a gate insulating layer formation step of forming the gate insulating layer such that the gate insulating layer covers the gate electrode; an oxide semiconductor layer formation step of depositing an oxide semiconductor film on the gate insulating layer, depositing a metal film on the oxide semiconductor film, and patterning the oxide semiconductor film and the metal film with a second photomask, thereby forming the oxide semiconductor layer and the source and drain electrodes; a protective layer formation step of forming the protective layer such that the protective layer covers the oxide semiconductor layer and the source and drain electrodes; an insulating layer formation step of forming an insulating layer on the protective layer; a contact hole formation step of patterning the protective layer and the insulating layer with a third photomask, thereby forming a contact hole in the protective layer and the insulating layer such that the contact hole reaches the drain electrode; and a terminal formation step of depositing a second conductive film on the protective layer and the insulating layer and patterning the second conductive film with a fourth photomask, thereby forming the pixel electrode and a second terminal line on the first terminal line such that the terminal including the first terminal line and the second terminal line is formed.

In this configuration, the first terminal line and the second terminal line constituting the terminal are made of a conductive material different from a material constituting the oxide semiconductor layer. Thus, it is possible to prevent exposure of the material constituting the oxide semiconductor layer at the side surface of the terminal. Accordingly, it is possible to prevent contact of the material constituting the oxide semiconductor layer with the air, and thereby, to prevent corrosion by moisture contained in the air. As a result, an electrical continuity failure of the terminal due to corrosion of the material constituting the oxide semiconductor layer can be prevented.

In addition, since the first terminal line and the second terminal line constituting the terminal are made of the conductive material different from the material constituting the oxide semiconductor layer, oxide semiconductor having a high etching rate does not need to be etched in forming the terminal. This can prevent over-etching of the first terminal line and the second terminal line constituting the terminal, resulting in prevention of an electrical continuity failure of the terminal due to increased resistance and disconnection of the first terminal line and the second terminal line.

In formation of the display device substrate, the first photomask is used in the first terminal line formation step, the second photomask is used in the oxide semiconductor layer formation step, the third photomask is used in the contact hole formation step, and the fourth photomask is used in the terminal formation step. That is, four photomasks are used in total. Thus, as compared to a conventional process using four masks, occurrence of an electrical continuity failure of the terminal due to corrosion of the material constituting the oxide semiconductor layer can be prevented without an increase in the number of photomasks.

### Advantages of the Invention

According to the present disclosure, it is possible to prevent occurrence of an electrical continuity failure due to corrosion of a material constituting an oxide semiconductor layer.

### BRIEF DESCRIPTION OF THE DRAWINGS

FIG. 1 is a cross-sectional view illustrating a liquid crystal display device including a display device substrate according to an embodiment of the present disclosure.

FIG. 2 is a plan view illustrating the liquid crystal display device including the display device substrate of the embodiment.

FIG. 3 is an enlarged plan view illustrating a pixel area and a terminal area of the liquid crystal display device including the display device substrate of the embodiment.

FIG. 4 is a cross-sectional view of the display device substrate taken along line A-A in FIG. 3.

FIG. 5 is a cross-sectional view of the liquid crystal display device taken along line B-B in FIG. 3.

FIG. 6 illustrates cross sections of process steps of forming a display device substrate according to the embodiment.

FIG. 7 illustrates cross sections of process steps of forming a terminal of the display device substrate of the embodiment.

FIG. 8 illustrates cross sections of process steps of forming the terminal of the display device substrate of the embodiment.

FIG. 9 illustrates cross sections of process steps of forming another display device substrate according to the embodiment.

FIG. 10 is a cross-sectional view illustrating a variation of the liquid crystal display device including the display device substrate of the embodiment.

FIG. 11 is a cross-sectional view illustrating a variation of the display device substrate of the embodiment.

FIG. 12 illustrates a cross section of a process step of forming the display device substrate illustrated in FIG. 11.

### DESCRIPTION OF EMBODIMENTS

An embodiment of the present disclosure will be described hereinafter with reference to the drawings. The present disclosure is not limited to the following embodiment.

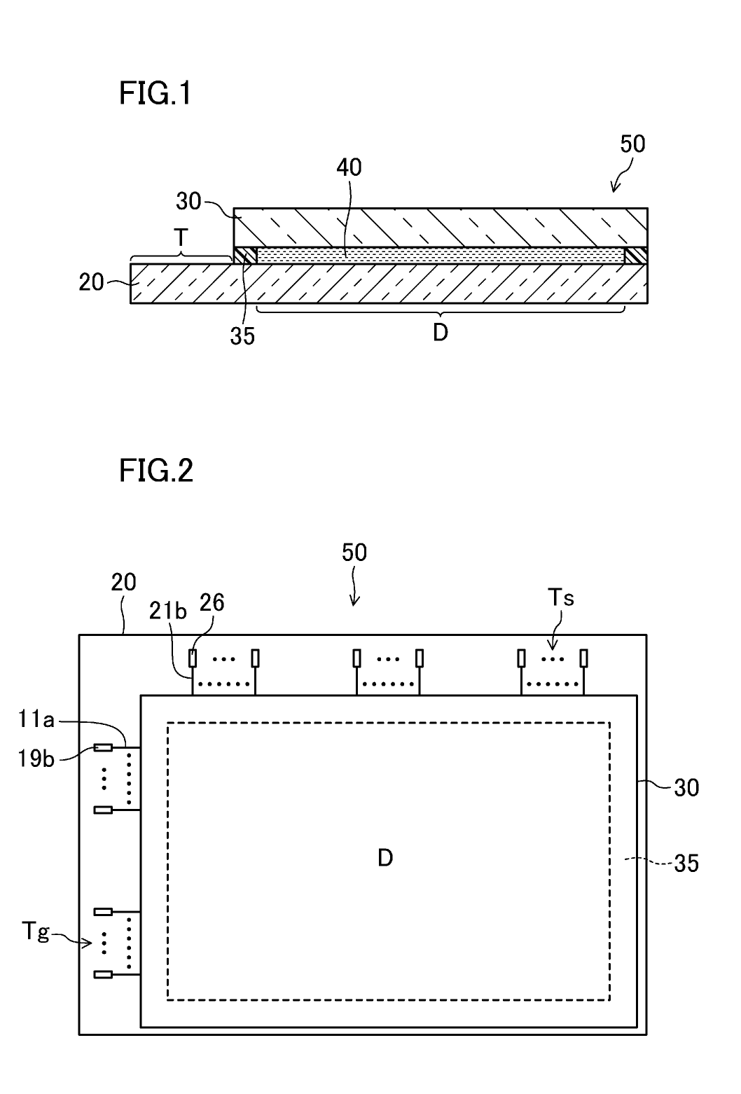

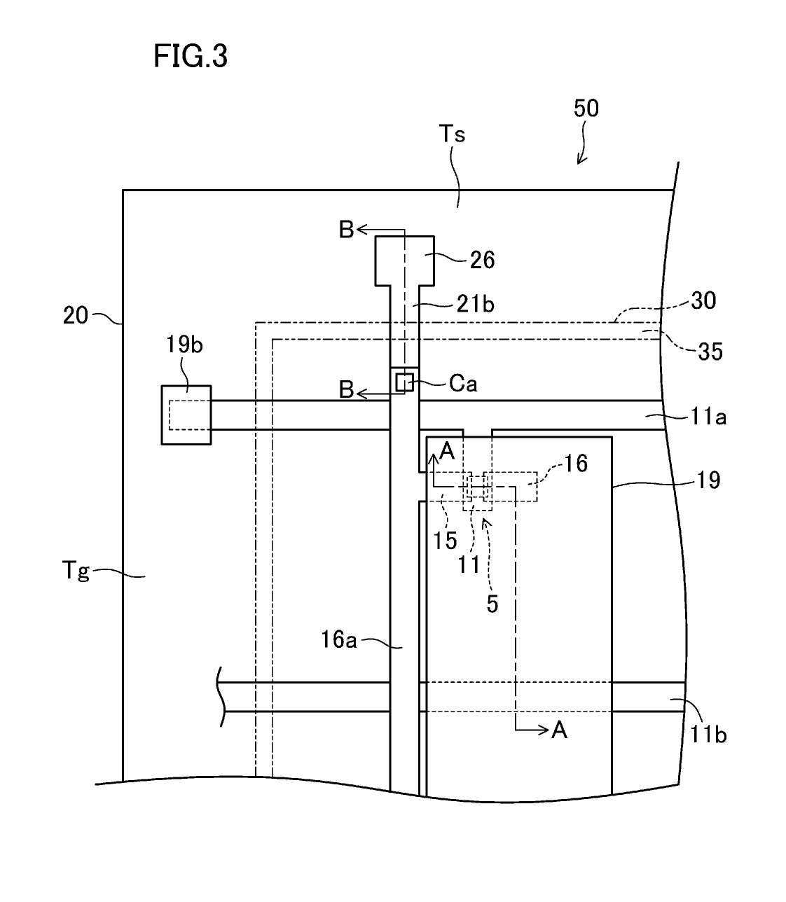

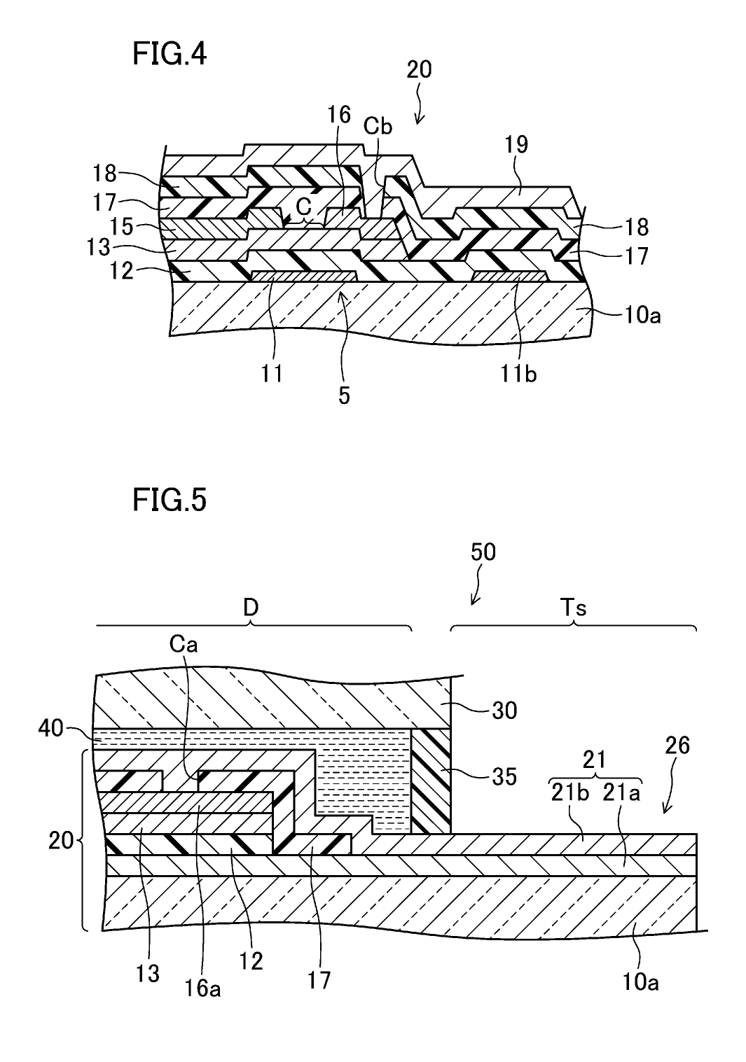

FIG. 1 is a cross-sectional view illustrating a liquid crystal display device including a display device substrate according to an embodiment of the present disclosure. FIG. 2 is a plan view illustrating the liquid crystal display device including the display device substrate of this embodiment. FIG. 3 is an enlarged plan view illustrating a pixel area and a terminal area of the liquid crystal display device including the display device substrate of this embodiment. FIG. 4 is a cross-sectional view of the display device substrate taken along line A-A in FIG. 3. FIG. 5 is a cross-sectional view of the liquid crystal display device taken along line B-B in FIG. 3.

As illustrated in FIG. 1, a liquid crystal display device 50 includes: an active matrix substrate 20 which is a display device substrate; a counter substrate 30 which is another display device substrate disposed to face the active matrix substrate 20; and a liquid crystal layer 40 which is a display medium layer and provided between the active matrix substrate 20 and the counter substrate 30.

The liquid crystal display device 50 also includes a sealing material 35 sandwiched between the active matrix substrate 20 and the counter substrate 30 to bond the active matrix substrate 20 and the counter substrate 30 together and having a frame shape for enclosing the liquid crystal layer 40 between the active matrix substrate 20 and the counter substrate 30.

As illustrated in FIGS. 1 and 2, in the liquid crystal display device 50, a display region D for displaying an image is defined inside the sealing material 35, and a terminal region T is defined on a portion of the active matrix substrate 20 located around the display region D (i.e., outside the sealing material 35) and projecting from the counter substrate 30 when viewed from above. That is, the sealing material 35 is located between the display region D and the terminal region T.

As illustrated in FIGS. 2, 3, and 4, the active matrix substrate 20 includes an insulating substrate 10a and also includes, in the display region D, a plurality of scanning lines 11a extending in parallel with each other on the insulating substrate 10a, a plurality of auxiliary capacitor lines 11b extending in parallel with the scanning lines 11a, and signal lines 16a orthogonal to the scanning lines 11a.

The active matrix substrate 20 also includes: a plurality of TFTs 5 provided at respective intersections of the scanning lines 11a and the signal lines 16a, i.e., for respective pixels; a protective layer 17 covering the TFTs 5; an insulating layer 18 covering the protective layer 17; pixel electrodes 19 arranged in a matrix on the insulating layer 18 and connected to the TFTs 5; and an alignment film (not shown) covering the pixel electrodes 19.

As illustrated in FIGS. 2 and 3, the scanning lines 11a extend to a gate terminal region Tg in the terminal region T (see FIG. 1), and is connected to gate terminals 19b in this gate terminal region Tg.

As illustrated in FIGS. 3 and 5, the signal lines 16a are connected to source terminals 26 provided in a source terminal region Ts through contact holes Ca formed in the protective layer 17.

In this embodiment, as illustrated in FIG. 5, the source terminals 26 are constituted by terminal lines 21 provided on the insulating substrate 10a. As illustrated in FIG. 5, the terminal lines 21 include, in the source terminal region Ts, first terminal lines 21a provided on the insulating substrate 10a and second terminal lines 21b provided on the first terminal lines 21a.

As illustrated in FIG. 5, the second terminal lines 21b are located on the protective layer 17 in the display region D defined inside the sealing material 35. The signal lines 16a are connected to the second terminal lines 21b constituting the source terminals 26 through the contact holes Ca formed in the protective layer 17.

In the terminal region T, the gate terminals 19b and the source terminals 26 are connected to external circuits (e.g., gate drivers and source drivers) for supplying external signals.

Each of the TFTs 5 has a bottom-gate structure and, as illustrated in FIGS. 3-5, includes: a gate electrode 11 provided on the insulating substrate 10a; a gate insulating layer 12 provided over the gate electrode 11; an oxide semiconductor layer 13 located on the gate insulating layer 12 and having an island-shape channel region C overlapping with the gate electrode 11; and source and drain electrodes 15 and 16 provided on the oxide semiconductor layer 13, overlapping with the gate electrode 11, and facing each other with the channel region C sandwiched therebetween.

In this structure, the protective layer 17 covering the oxide semiconductor layer 13 and the source and drain electrodes 15 and 16 (i.e., the TFTs 5) is provided on the channel region C of the oxide semiconductor layer 13. The insulating layer 18 is provided on the protective layer 17.

As illustrated in FIG. 3, the gate electrode 11 projects from a side of an associated one of the scanning lines 11a. As also illustrated in FIG. 3, the source electrode 15 projects from a side of an associated one of the signal lines 16a. As illustrated in FIG. 4, the drain electrode 16 is connected to an associated one of the pixel electrodes 19 through a contact hole Cb formed in the stack of the protective layer 17 and the insulating layer 18.

Examples of a material constituting the oxide semiconductor layer 13 include an IGZO (In—Ga—Zn—O)-based oxide semiconductor.

As illustrated in FIG. 5, in this embodiment, the sealing material 35 is located on the surface of the terminal line 21. Specifically, the sealing material 35 is located on the surface of the terminal line 21 made of a conductive material different from that of a material (i.e., oxide semiconductor) constituting the oxide semiconductor layer 13. Thus, it is possible to prevent a variation of stress on the sealing material 35 due to expansion and contraction of bubbles included in the oxide semiconductor.

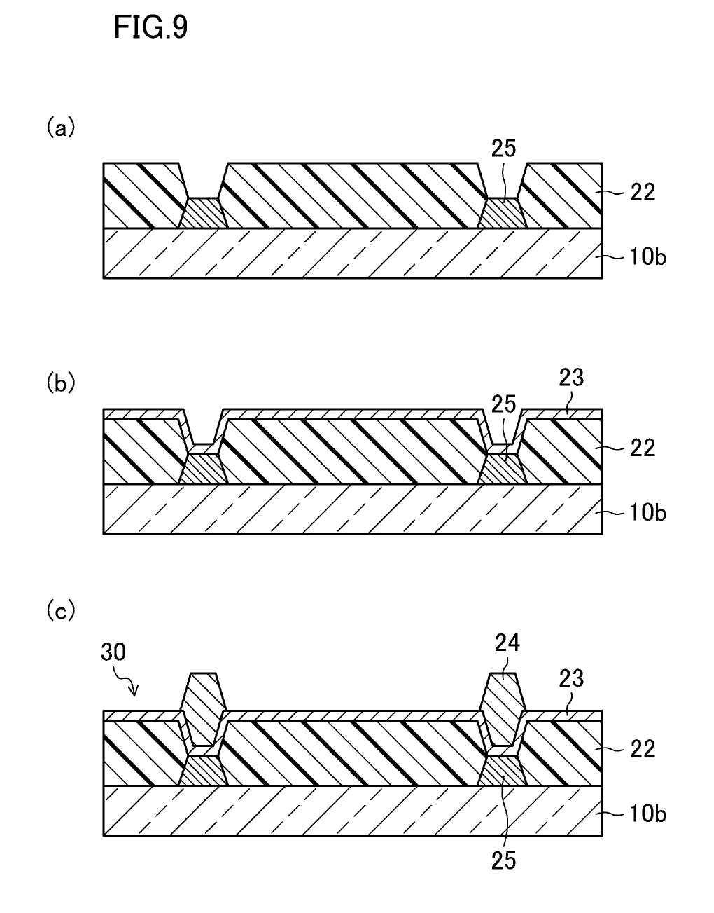

As illustrated in FIG. 9(c), which will be referred to later, the counter substrate 30 includes: an insulating substrate 10b; a color filter layer located on the insulating substrate 10b and including a lattice-shaped black matrix 25 and colored films 22, such as a red film, a green film, and a blue film, provided in the respective lattices of the black matrix 25; a common electrode 23 covering the color filter layer, photospacers 24 located on the common electrode 23; and an alignment film (not shown) covering the common electrode 23.

The liquid crystal layer 40 is made of, for example, a nematic liquid crystal material having electrooptic properties.

In each of the pixels in the liquid crystal display device 50 having the above-described configuration, when a gate signal is transmitted from the gate driver (not shown) to the gate electrode 11 through the scanning line 11a to turn on the TFT 5, a source signal is sent from the source driver (not shown) to the source electrode 15 through the signal line 16a, thereby writing a predetermined amount of charge in the pixel electrode 19 through the oxide semiconductor layer 13 and the drain electrode 16.

In this process, a potential difference occurs between the pixel electrode 19 of the active matrix substrate 20 and the common electrode 23 of the counter substrate 30, resulting in that a predetermined voltage is applied to the liquid crystal layer 40, i.e., a liquid crystal capacitor of each pixel and an auxiliary capacitance connected to the liquid crystal capacitor in parallel.

In each of the pixels in the liquid crystal display device 50, the alignment state of the liquid crystal layer 40 is changed depending on the level of the voltage applied to the liquid crystal layer 40. In this manner, an image is displayed with adjustment of the light transmittance of the liquid crystal layer 40.

As a feature of this embodiment, the terminal lines 21 (i.e., the first terminal lines 21a and the second terminal lines 21b) constituting the source terminals 26 are made of a conductive material different from a material (i.e., oxide semiconductor) constituting the oxide semiconductor layer 13.

More specifically, the first terminal lines 21a are made of, for example, a conductive material (a metal material) such as titanium, aluminium, molybdenum, tungsten, tantalum, chromium, copper, or an alloy containing at least one of these elements.

The second terminal lines 21b are made of, for example, a conductive material such as indium tin oxide (ITO), indium zinc oxide (IZO), indium tin oxide containing silicon oxide (ITSO), indium oxide (In₂O₃), tin oxide (SnO₂), zinc oxide (ZnO), or titanium nitride (TiN).

As described above, since the terminal lines 21 constituting the source terminals 26 are made of a conductive material different from the material constituting the oxide semiconductor layer 13, exposure of oxide semiconductor at the side surfaces of the source terminals 26 can be prevented. As a result, it is possible to prevent corrosion of oxide semiconductor by moisture in the air due to contact with the air.

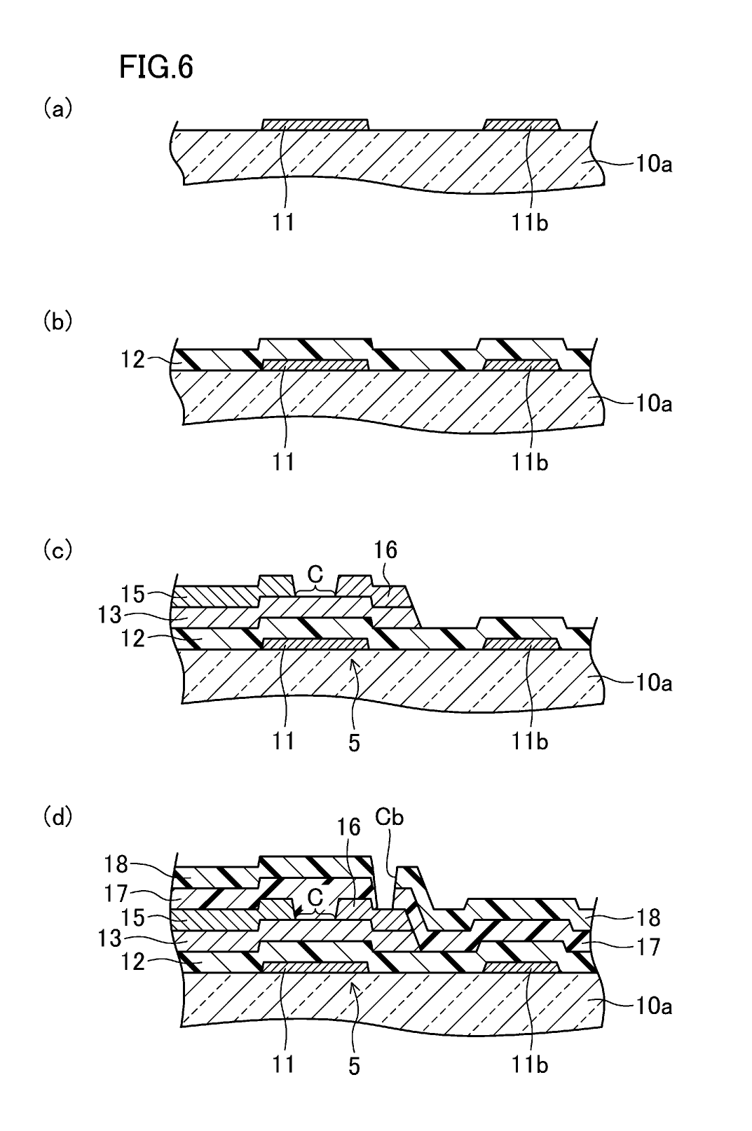

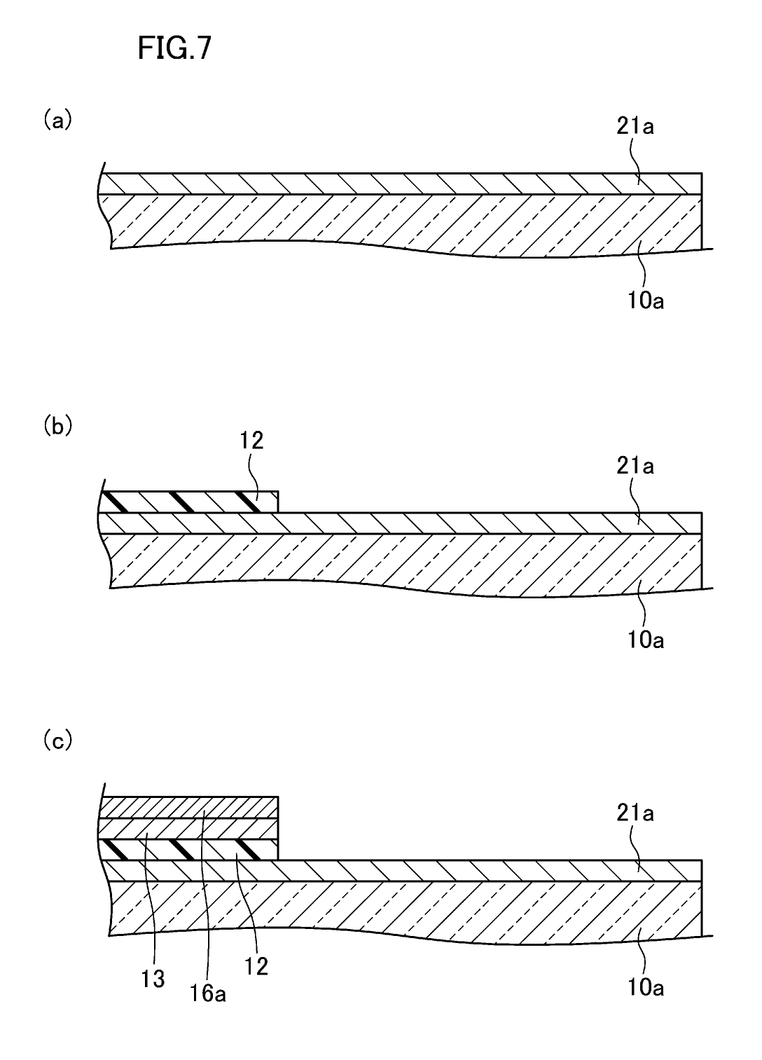

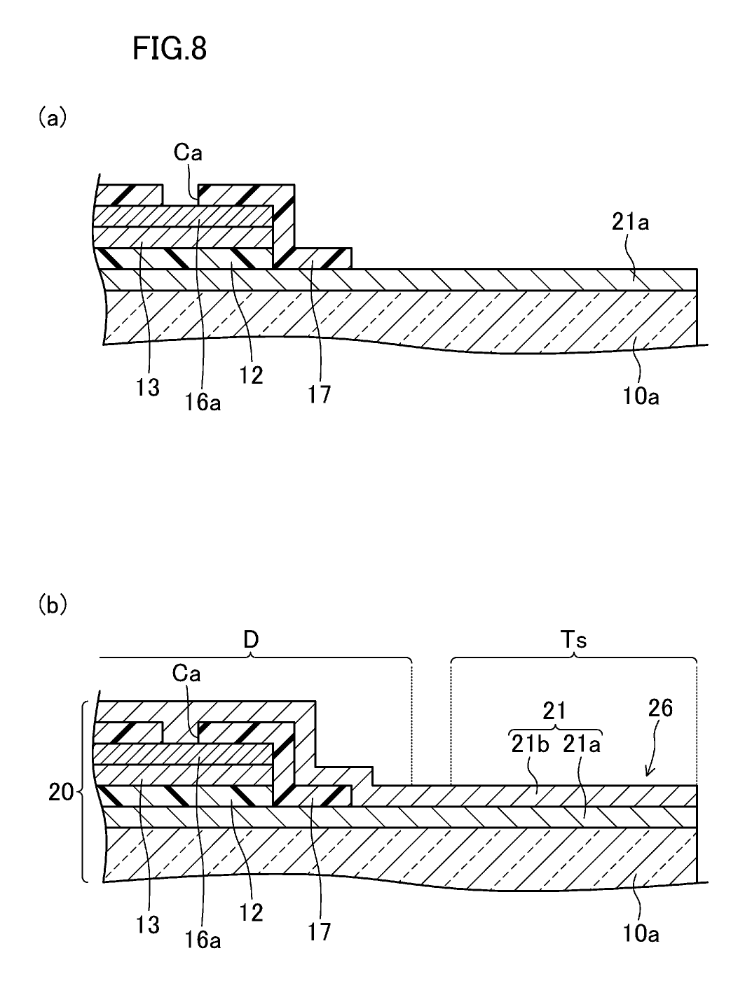

Next, an example method for fabricating the liquid crystal display device 50 according to this embodiment will be described with reference to FIGS. 6-9. FIG. 6 illustrates cross sections of process steps of forming a display device substrate according to the embodiment. FIG. 7 illustrates cross sections of process steps of forming a terminal of the display device substrate of the embodiment. FIG. 8 illustrates cross sections of process steps of forming the terminal of the display device substrate of the embodiment. FIG. 9 illustrates cross sections of process steps of forming another display device substrate according to the embodiment.

Process steps of forming TFTs and an active matrix substrate will now be described.

<Gate Electrode and First Terminal Line Formation Step>

First, a first conductive film of a conductive material as a stack of, for example, a titanium film (with a thickness of about 100 nm), an aluminium film (with a thickness of about 200 nm), and a titanium film (with a thickness of about 30 nm) is deposited by sputtering over the entire surface of an insulating substrate 10a such as a glass substrate. Then, patterning by photolithography with a first photomask, dry etching of the first conductive film, removal of a resist, and irrigation are performed, thereby forming scanning lines 11a, gate electrodes 11, auxiliary capacitor lines 11b, and first terminal lines 21a, as illustrated in FIGS. 3, 6(a), and 7(a).

As described above, in this embodiment, the first terminal lines 21a and the gate electrodes 11 are made of an identical material. Accordingly, it is possible to form the first terminal lines 21a and the gate electrodes 11 at the same time, resulting in that the first terminal lines 21a can be easily formed and an increase in the number of process steps can be reduced.

<Gate Insulating Layer Formation Step>

Next, a silicon nitride film (with a thickness of about 200-500 nm), for example, is deposited by plasma CVD over the entire substrate on which the scanning lines 11a, the gate electrodes 11, the auxiliary capacitor lines 11b, and the first terminal lines 21a are formed, thereby forming a gate insulating layer 12 covering the gate electrodes 11, the auxiliary capacitor lines 11b, and the first terminal lines 21a, as illustrated in FIGS. 6(b) and 7(b).

The gate insulating layer 12 may be made of a stack of two layers. In this case, in addition to the silicon nitride film (SiNx), a silicon oxide film (SiOx), a silicon oxynitride film (SiOxNy, x>y), or a silicon nitride oxide film (SiNxOy, x>y), for example, may be used.

To prevent diffusion of, for example, an impurity from the insulating substrate 10a, a silicon nitride film or a silicon nitride oxide film is preferably used as a lower gate insulating layer, whereas a silicon oxide film or a silicon oxynitride film is preferably used as an upper gate insulating layer. For example, a silicon nitride film with a thickness of 150-400 nm may be formed as a lower gate insulating layer using SiH₄ and NH₃ as a reactant gas, and a silicon oxide film with a thickness of 50-100 nm may be formed using N₂O and SiH₄ as a reactant gas.

To deposit a dense gate insulating layer 12 with a small gate leakage current at a low temperature, a rare gas such as an argon gas is preferably contained in the reactant gas to be mixed in the insulating layer.

<Oxide Semiconductor Layer, Source and Drain Formation Step>

Thereafter, an oxide semiconductor film (with a thickness of about 50 nm) of, for example, indium gallium zinc oxide (IGZO) is deposited by spattering. Then, a metal film as a stack of, for example, a titanium film (with a thickness of about 100 nm), an aluminium film (with a thickness of about 200 nm), and a titanium film (with a thickness of about 30 nm) is formed by spattering.

Subsequently, the metal film is patterned by photolithography with a second photomask and dry etched, thereby forming signal lines 16a, source electrodes 15, and drain electrodes 16 and exposing a portion to be a channel region C of an oxide semiconductor layer 13, as illustrated in FIGS. 3, 6(c), and 7(c).

Then, patterning of the oxide semiconductor film by photolithography with a second photomask, wet etching of the oxide semiconductor film, removal of a resist, and irrigation are performed, thereby forming an oxide semiconductor layer 13 and TFTs 5 as illustrated in FIGS. 6(c) and 7(c).

In this embodiment, exposure (halftone exposure or graytone exposure) is performed using a halftone mask or a graytone mask as a second photomask, and a resist for forming the oxide semiconductor layer 13, the source electrodes 15, the drain electrodes 16, and the signal lines 16a is formed with a single mask (i.e., the second photomask).

<Protective Layer Formation Step>

Thereafter, a silicon oxide film, a silicon nitride film, or a silicon nitride oxide film, for example, is deposited by plasma CVD to a thickness of about 265 nm over the entire surface of the substrate on which the source and drain electrodes 15 and 16 (i.e., the TFTs 5) are formed, thereby forming a protective layer 17 covering the oxide semiconductor layer 13, the source electrodes 15, the drain electrodes 16, and the signal lines 16a, as illustrated in FIGS. 6(d) and 8(a).

<Insulating Layer Formation Step>

Subsequently, a photosensitive organic insulating film of, for example, a photosensitive acrylic resin is deposited to a thickness of about 2.5 μm over the protective layer 17, thereby forming an insulating layer 18 covering the protective layer 17, as illustrated in FIG. 6(d).

<Contact Hole Formation Step>

Then, patterning of the protective layer 17 and the insulating layer 18 by photolithography with a third photomask, dry etching of the protective layer 17 and the insulating layer 18, removal of a resist, and irrigation are performed, thereby forming contact holes Cb which reach the drain electrodes 16 through the protective layer 17 and the insulating layer 18 and contact holes Ca which reach the signal lines 16a through the protective layer 17, as illustrated in FIGS. 6(d) and 8(a).

<Pixel Electrode and Source Terminal Formation Step>

Thereafter, a second conductive film such as an ITO film (with a thickness of about 50-200 nm) of indium tin oxide, for example, is deposited by spattering over the protective layer 17 and the insulating layer 18. Then, patterning of the second conductive film by photolithography with a fourth photomask, wet etching of the second conductive film, removal of a resist, and irrigation are performed, thereby forming pixel electrodes 19 and gate terminals 19b, forming second terminal lines 21b on first terminal lines 21a to form terminal lines 21 including the first terminal lines 21a and the second terminal lines 21b, and forming source terminals 26 constituted by the terminal lines 21, as illustrated in FIGS. 3, 4, and 8(b).

As described above, in this embodiment, the second terminal lines 21b and the pixel electrodes 19 are made of an identical material. Accordingly, it is possible to form the second terminal lines 21b and the pixel electrodes 19 at the same time, resulting in that the second terminal lines 21b can be easily formed and an increase in the number of process steps can be reduced.

In conventional techniques, source terminals are constituted by an oxide semiconductor layer and signal lines as described above. Thus, in forming the source terminals, etching of oxide semiconductor with a high etching rate might cause over-etching of the signal lines to reduce the line width of the signal lines. Reduction of the line width of the signal lines can cause problems such as increased resistance and disconnection of the signal lines, resulting in an electrical continuity failure of the source terminals constituted by the signal lines.

On the other hand, in this embodiment, the source terminals 26 are constituted by the terminal lines 21 on the insulating substrate 10a, and the terminal lines 21 are made of a conductive material different from a material constituting the oxide semiconductor layer, as described above. Thus, in forming the source terminals 26, it is unnecessary to etch oxide semiconductor with a high etching rate. Accordingly, over-etching of the terminal lines 21 constituting the source terminals 26 can be prevented, resulting in prevention of an electrical continuity failure of the terminals due to increased resistance and disconnection of the terminal lines 21.

In the case of a transmissive liquid crystal display device 50, the pixel electrodes 19 may include indium oxide or indium zinc oxide containing tungsten oxide, or include indium oxide or indium tin oxide containing titanium oxide, for example. Instead of indium tin oxide described above, indium zinc oxide or indium tin oxide containing silicon oxide, for example, may be used.

In the case of a reflective liquid crystal display device 50, a conductive film of titanium, tungsten, nickel, gold, platinum, silver, aluminium, magnesium, calcium, lithium, or an alloy containing at least one of these elements may be used as a reflective metal thin film, and this metal thin film may be used for the pixel electrodes 19.

In the foregoing manner, an active matrix substrate 20 illustrated in FIGS. 4 and 8(b) can be formed.

<Counter Substrate Formation Step>

First, the entire surface of the insulating substrate 10b such as a glass substrate is coated with, for example, a black-colored photosensitive resin by spin coating or slit coating, and then is exposed to light and developed, thereby forming a black matrix 25 with a thickness of about 1.0 μm, as illustrated in FIG. 9(a).

Next, the entire substrate including the black matrix 25 is coated with a red-, green-, or blue-colored photosensitive resin by spin coating or slit coating, and then is exposed to light and developed, thereby forming a colored film 22 of a selected color (e.g., a red film) with a thickness of about 2.0 μm, as illustrated in FIG. 9(a). Similar processes are performed for the other two colors, thereby forming colored films 22 of the other two colors (e.g., a green film and a blue film) each with a thickness of about 2.0 μm.

Then, a transparent conductive film such as an ITO film, for example, is deposited by spattering over the substrate including the colored films 22, thereby forming a common electrode 23 with a thickness of about 50-200 nm, as illustrated in FIG. 9(b).

Lastly, the entire substrate including the common electrode 23 is coated with a photosensitive resin by spin coating or slit coating, and then is exposed to light and developed, thereby forming photospacers 24 each with a thickness of about 4 μm, as illustrated in FIG. 9(c).

In the foregoing manner, a counter substrate 30 is formed.

<Liquid Crystal Injection Step>

First, a resin film of polyimide is applied by printing onto the surfaces the active matrix substrate 20 formed by the above-descried active matrix substrate formation step and the counter substrate 30 formed by the above-descried counter substrate formation step, and is subjected to calcination and rubbing, thereby forming an alignment film.

Next, a sealing material 35 of, for example, an ultraviolet (UV)/thermosetting resin is printed in a frame shape on the surface of the counter substrate 30 on which the alignment film is formed, and then a liquid crystal material is dropped inside the frame of the sealing material 35.

Thereafter, the counter substrate 30 on which the liquid crystal material has been dropped and the active matrix substrate 20 on which the alignment film is formed are bonded together under a reduced pressure to form a bonded assembly. This bonded assembly is then exposed to the air under an atmospheric pressure, thereby pressurizing the front and back surfaces of the bonded assembly.

Subsequently, the sealing material 35 enclosed in the bonded assembly is irradiated with UV light, and then the bonded assembly is heated, thereby curing the sealing material 35.

Lastly, the bonded assembly enclosing the cured sealing material 35 is diced, for example, and unwanted portions thereof are removed.

In the foregoing manner, the liquid crystal display device 50 illustrated in FIGS. 1-3 and 5 is fabricated.

In a manner similar to the above-described conventional techniques, in formation of the active matrix substrate 20 of this embodiment, the first photomask is used in the first terminal line formation step, the second photomask is used in the oxide semiconductor layer formation step, the third photomask is used in the contact hole formation step, and the fourth photomask is used in the terminal formation step. That is, four photomasks are used in total. Thus, as compared to a conventional process using four masks, occurrence of an electrical continuity failure of the source terminals 26 due to corrosion of oxide semiconductor can be prevented without an increase in the number of photomasks.

The foregoing embodiment can obtain the following advantages.

(1) In this embodiment, the source terminals 26 are constituted by the terminal lines 21 formed on the insulating substrate 10a. In addition, the terminal lines 21 are made of a conductive material different from a material constituting the oxide semiconductor layer 13. Thus, exposure of oxide semiconductor at the side surfaces of the source terminals 26 can be prevented. Accordingly, in the source terminals 26, it is possible to prevent contact of oxide semiconductor with the air, and thereby, to prevent corrosion of oxide semiconductor by moisture contained in the air. As a result, an electrical continuity failure of the source terminals 26 due to corrosion of oxide semiconductor can be prevented.

(2) The source terminals 26 are constituted by the terminal lines 21 formed on the insulating substrate 10a, and the terminal lines 21 are made of a conductive material different from a material constituting the oxide semiconductor layer. Thus, in forming the source terminals 26, it is unnecessary to etch oxide semiconductor having a high etching rate. Consequently, over-etching of the terminal lines 21 constituting the source terminals 26 can be prevented, resulting in prevention of occurrence of an electrical continuity failure of terminals due to increased resistance and disconnection of terminal lines 21.

(3) In this embodiment, the first terminal lines 21a and the gate electrodes 11 are made of an identical material. Accordingly, the first terminal lines 21a and the gate electrodes 11 can be formed at the same time. Thus, the first terminal lines 21a can be easily formed, and an increase in the number of process steps can be reduced. As a result, the manufacturing cost can be reduced.

(4) In this embodiment, the second terminal lines 21b and the pixel electrodes 19 are made of an identical material. Accordingly, the second terminal lines 21b and the pixel electrodes 19 can be formed at the same time. Thus, the second terminal lines 21b can be easily formed, and an increase in the number of process steps can be reduced. As a result, the manufacturing cost can be reduced.

(5) In this embodiment, the sealing material 35 is provided on the surfaces of the terminal lines 21. Accordingly, it is possible to prevent a variation of stress on the sealing material 35 due to expansion and contraction of bubbles included in oxide semiconductor. As a result, occurrence of peeling and cracks in the sealing material 35 caused by oxide semiconductor can be prevented.

The above embodiment may be modified in the following manner.

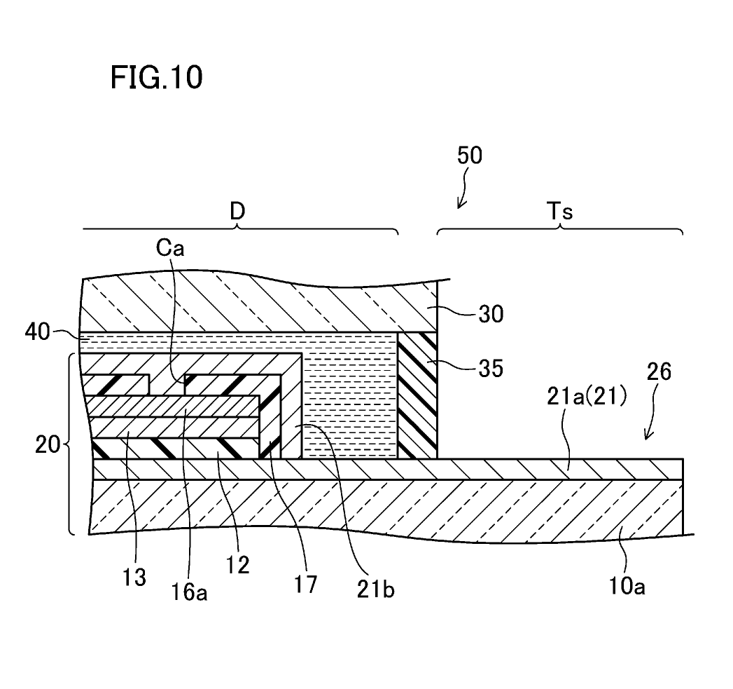

In the above embodiment, the source terminals 26 include the first terminal lines 21a and the second terminal lines 21b. Alternatively, as illustrated in FIG. 10, in the source terminal region Ts, the terminal lines 21 constituting the source terminals 26 may include only the first terminal lines 21a with no the second terminal lines 21b.

In this case, after the process steps from the gate insulating layer formation step to the contact hole formation step described in the above embodiment, a transparent conductive film such as an ITO film (with a thickness of about 50-200 nm) of indium tin oxide, for example, is deposited by spattering over the entire surface of the substrate on which the protective layer 17 and the insulating layer 18 are formed. Then, patterning of the transparent conductive film by photolithography with a fourth photomask, wet etching of the transparent conductive film, removal of a resist, and irrigation are performed, thereby forming the pixel electrodes 19, the gate terminals 19b, and the second terminal lines 21b. At this time, as illustrated in FIG. 10, the second terminal lines 21b are formed in the display region D. Thereafter, in the same manner as in the above embodiment, the counter substrate formation step and the liquid crystal injection step are performed, thereby fabricating a liquid crystal display device. In such a configuration, advantages (1)-(3) and (5) described above can be obtained.

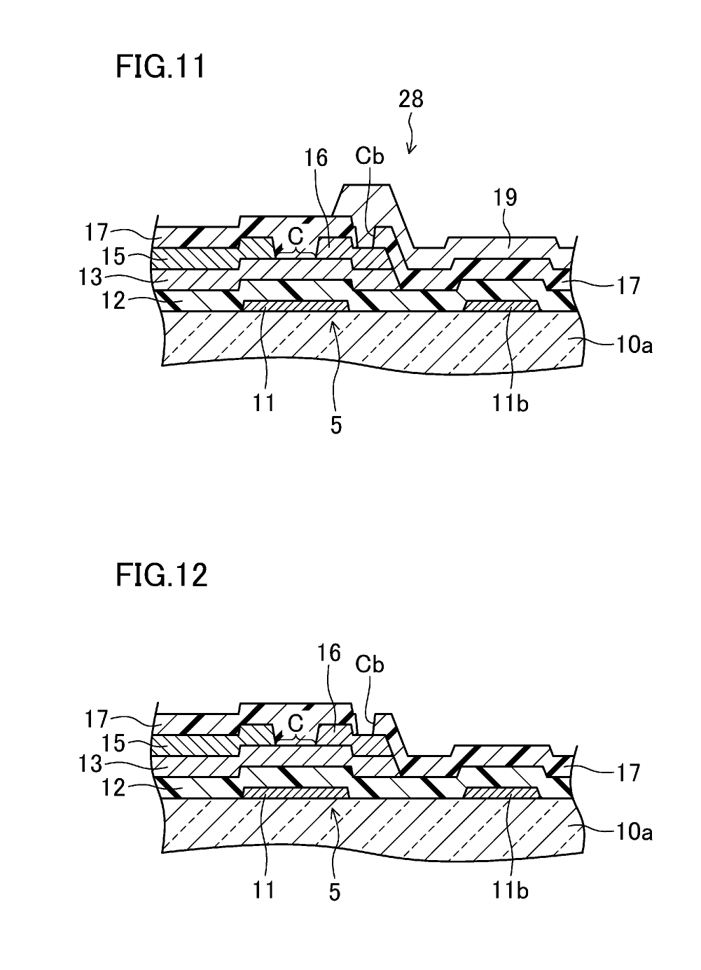

In the above embodiment, the insulating layer 18 is formed on the protective layer 17. Alternatively, to simplify the processes, as illustrated in FIG. 11, the active matrix substrate 28 may be configured such that the insulating layer 18 is not provided and the pixel electrodes 19 are formed on the protective layer 17.

In this case, the gate electrode and first terminal line formation step, the gate insulating layer formation step, and the oxide semiconductor layer, source, and drain formation step described above and illustrated in FIGS. 6(a)-6(c) and 7(a)-7(c) are performed. Thereafter, as the protective layer formation step, a silicon oxide film, a silicon nitride film, or a silicon nitride oxide film, for example, is formed by plasma CVD to a thickness of about 265 nm over the entire substrate of the substrate on which the source and drain electrodes 15 and 16 (i.e., the TFTs 5) are formed, thereby forming a protective layer 17 covering the oxide semiconductor layer 13, the source electrodes 15, the drain electrodes 16, and the signal lines 16a, as illustrated in FIGS. 12 and 8(a).

Then, as the contact hole formation step, patterning of the protective layer 17 by photolithography with the third photomask, dry etching of the protective layer 17, removal of a resist, and irrigation are performed, thereby forming contact holes Cb reaching the drain electrodes 16 through the protective layer 17 and contact holes Ca reacting the signal lines 16a through the protective layer 17, as illustrated in FIGS. 12 and 8(a).

Subsequently, as the pixel electrode and source terminal formation step, a second conductive film such as an ITO film (with a thickness of about 50-200 nm) of, for example, indium tin oxide is deposited by spattering over the protective layer 17. Then, patterning of the second conductive film by photolithography with the fourth photomask, wet etching of the second conductive film, removal of a resist, and irrigation are performed, thereby forming the pixel electrodes 19 and the gate terminals 19b, and also forming the second terminal lines 21b on the first terminal lines 21a to form the terminal lines 21 including the first terminal lines 21a and the second terminal lines 21b provided on the first terminal lines 21a so that the source terminals 26 constituted by the terminal lines 21 are formed, as illustrated in FIGS. 3, 11, and 8(b). Such a configuration can also obtain advantages (1)-(5) described above.

In the above embodiment, an oxide semiconductor layer of indium gallium zinc oxide (IGZO) is used as the oxide semiconductor layer 13. However, the oxide semiconductor layer 13 is not limited to this embodiment, and may be made of metal oxide containing at least one of indium (In), gallium (Ga), aluminium (Al), copper (Cu), zinc (Zn), magnesium (Mg), or cadmium (Cd).

Even if the oxide semiconductor layer 13 made of the above-described material is amorphous, high mobility thereof can increase the ON resistance of switching devices. Accordingly, the difference in output voltage in reading data is increased, thereby enhancing the S/N ratio. Instead of IGZO (In—Ga—Zn—O), an oxide semiconductor film of InGaO₃(ZnO)₅, MgₓZn₁₋ₓO, CdₓZn₁₋ₓO, or CdO, for example, may be used.

### INDUSTRIAL APPLICABILITY

The present disclosure is applicable to a display device substrate including a thin-film transistor using an oxide semiconductor layer, a method for forming the substrate, and a display device, for example.

### DESCRIPTION OF REFERENCE CHARACTERS

5 thin-film transistor
10a insulating substrate
11 gate electrode
11a scanning lines 11a
11b auxiliary capacitance line
12 gate insulating layer
13 oxide semiconductor layer
15 source electrode
16 drain electrode
16a signal line
17 protective layer
18 insulating layer
19 pixel electrode
20 active matrix substrate (display device substrate)
21 terminal line
21a first terminal line
21b second terminal line
26 gate terminal (terminal)
28 active matrix substrate (display device substrate)
30 counter substrate (another display device substrate)
35 sealing material
40 liquid crystal layer (display medium layer)
50 liquid crystal display device (display device)
C channel region
D display region
T terminal region
Ts source terminal region
Tg gate terminal region

1. A display device substrate, comprising:
an insulating substrate;
a gate electrode provided on the insulating substrate;
a gate insulating layer covering the gate electrode;
an oxide semiconductor layer provided on the gate insulating layer and having a channel region overlapping with the gate electrode;
source and drain electrodes provided on the oxide semiconductor layer, overlapping with the gate electrode, and facing each other with the channel region sandwiched therebetween;
a protective layer covering the oxide semiconductor layer and the source and drain electrodes; and
a pixel electrode provided on the protective layer, wherein
the display device substrate has a display region where an image is displayed and a terminal region located around the display region and including a terminal for connection to an external circuit,
the terminal includes a terminal line provided on the insulating substrate, and
the terminal line is made of a conductive material different from a material constituting the oxide semiconductor layer.

2. The display device substrate of claim 1, further comprising
an insulating layer provided on the protective layer.

3. The display device substrate of claim 1, wherein
the terminal line and the gate electrode are made of an identical material.

4. The display device substrate of claim 1, wherein
the terminal line includes a first terminal line provided on the insulating substrate and a second terminal line provided on the first terminal line.

5. The display device substrate of claim 4, wherein
the first terminal line and the gate electrode are made of an identical material, and
the second terminal line and the pixel electrode are made of an identical material.

6. The display device substrate of claim 1, wherein
the oxide semiconductor layer is made of indium gallium zinc oxide (IGZO).

7. A display device, comprising:
the display device substrate of claim 1;
another display device substrate opposed to the display device substrate; and
a display medium layer provided between the display device substrate and the another display device substrate.

8. The display device of claim 7, further comprising:
a sealing material held between the display device substrate and the another display device substrate and having a frame shape to enclose the display medium layer between the display device substrate and the another display device substrate, wherein
the sealing material is provided on a surface of the terminal line.

9. The display device of claim 7, wherein
the display medium layer is a liquid crystal layer.

10. A method for forming a display device substrate including:
an insulating substrate;
a gate electrode provided on the insulating substrate;
a gate insulating layer covering the gate electrode;
an oxide semiconductor layer provided on the gate insulating layer and having a channel region overlapping with the gate electrode;
source and drain electrodes provided on the oxide semiconductor layer, overlapping with the gate electrode, and facing each other with the channel region sandwiched therebetween;
a protective layer covering the oxide semiconductor layer and the source and drain electrodes; and
a pixel electrode provided on the protective layer,
the display device substrate having a display region where an image is displayed and a terminal region located around the display region and including a terminal for connection to an external circuit,
the method comprising:
a first terminal line formation step of depositing a first conductive film on the insulating substrate and patterning the first conductive film with a first photomask, thereby forming the gate electrode and a first terminal line;
a gate insulating layer formation step of forming the gate insulating layer such that the gate insulating layer covers the gate electrode;
an oxide semiconductor layer formation step of depositing an oxide semiconductor film on the gate insulating layer, depositing a metal film on the oxide semiconductor film, and patterning the oxide semiconductor film and the metal film with a second photomask, thereby forming the oxide semiconductor layer and the source and drain electrodes;
a protective layer formation step of forming the protective layer such that the protective layer covers the oxide semiconductor layer and the source and drain electrodes;
a contact hole formation step of patterning the protective layer with a third photomask, thereby forming a contact hole in the protective layer such that the contact hole reaches the drain electrode; and
a terminal formation step of depositing a second conductive film on the protective layer and patterning the second conductive film with a fourth photomask, thereby forming the pixel electrode and a second terminal line on the first terminal line such that the terminal including the first terminal line and the second terminal line is formed.

11. A method for forming a display device substrate including:
an insulating substrate;
a gate electrode provided on the insulating substrate;
a gate insulating layer covering the gate electrode;
an oxide semiconductor layer provided on the gate insulating layer and having a channel region overlapping with the gate electrode;
source and drain electrodes provided on the oxide semiconductor layer, overlapping with the gate electrode, and facing each other with the channel region sandwiched therebetween;
a protective layer covering the oxide semiconductor layer and the source and drain electrodes;
an insulating layer provided on the protective layer; and
a pixel electrode provided on the insulating layer,
the display device substrate having a display region where an image is displayed and a terminal region located around the display region and including a terminal for connection to an external circuit,
the method comprising:
a first terminal line formation step of depositing a first conductive film on the insulating substrate and patterning the first conductive film with a first photomask, thereby forming the gate electrode and a first terminal line;
a gate insulating layer formation step of forming the gate insulating layer such that the gate insulating layer covers the gate electrode;
an oxide semiconductor layer formation step of depositing an oxide semiconductor film on the gate insulating layer, depositing a metal film on the oxide semiconductor film, and patterning the oxide semiconductor film and the metal film with a second photomask, thereby forming the oxide semiconductor layer and the source and drain electrodes;
a protective layer formation step of forming the protective layer such that the protective layer covers the oxide semiconductor layer and the source and drain electrodes;
an insulating layer formation step of forming an insulating layer on the protective layer;
a contact hole formation step of patterning the protective layer and the insulating layer with a third photomask, thereby forming a contact hole in the protective layer and the insulating layer such that the contact hole reaches the drain electrode; and
a terminal formation step of depositing a second conductive film on the protective layer and the insulating layer and patterning the second conductive film with a fourth photomask, thereby forming the pixel electrode and a second terminal line on the first terminal line such that the terminal including the first terminal line and the second terminal line is formed.
